(19) United States
(12) Patent Application Publication
(10) Pub. No.: US 2004/0051569 A1
(43) Pub. Date: Mar. 18, 2004

(54) Register controlled delay locked loop

(76) Inventor: Young-Jin Jeon, Kyoungki-do (KR)

Correspondence Address: MARSHALL, GERSTEIN & BORUN LLP, 6300 SEARS TOWER, 233 S. WACKER DRIVE, CHICAGO, IL, 60606, US

(21) Appl. No.: 10/329,012

(22) Filed: Dec. 24, 2002

(30) Foreign Application Priority Data
Sep. 12, 2002 (KR) 2002-55262

(51) Int. Cl. H03L 7/00

(52) U.S. Cl. 327/153

(57) ABSTRACT

A register controlled DLL is used in generating a delay locked clock synchronized with an external clock, the external clock being used in generating an internal clock. The register controlled DLL includes a first clock dividing circuit for dividing the internal clock by 1/N to generate a inverted and divided internal clock, N being a positive integer; a delay line for delaying the internal clock by a first delay amount wherein the first delay amount is updated by a control signal to generate a delayed internal clock; a second clock dividing circuit for dividing the delayed internal clock by 1/N to generate a divided and delayed internal clock; a delay model circuit for receiving and delaying the divided and delayed internal clock by a second delay amount to generating a delay model clock; a phase comparison circuit for comparing a phase of the delay model clock with that of the inverted and delayed internal clock to generate a comparison signal representing a difference therebetween; and a delay controlling circuit for generating the control signal in response to the comparison signal to thereby allowing the register controlled DLL to generate the delay locked clock.

### BACKGROUND

1. Technical Field

The present invention relates to a semiconductor device and, more particularly, to a register controlled delay locked loop circuit (DLL), for use in the semiconductor device employing a reduced number of delay lines.

2. Description of the Related Art

Generally, a clock is used in various systems and circuitry as a reference for adjusting an operating timing and securing a much faster operation without error. When an external clock inputted from an external circuit is employed in an internal circuit, a time delay (i.e., a clock skew) is incurred due to circuit components of the internal circuit. At this time, a delay locked loop (hereinafter, referred to as a DLL) is used to compensate for such a time delay so that an internal clock can have the same phase as the external clock.

Meanwhile, because DLLs are not greatly affected by noise as compared with phase locked loops (PLL) that are typically used, DLLs are widely used in synchronous semiconductor memory devices, including a double data rate synchronous DRAM (DDR SDRAM). Among them, a register controlled DLL is more typically used.

In the synchronous semiconductor memory device, a register controlled DLL receives the external clock to compensate for delay components of actual clock paths and data paths, and a negative delay is in advance fed back. Through these procedures, the DLL is used to synchronize a data output with the external clock.

FIG. 1 is a block diagram of a conventional register controlled DLL in an SDRAM.

As shown in FIG. 1, the conventional register controlled DLL uses an internal clock INT_CLK outputted from a clock input buffer 10. The clock input buffer 10 temporarily stores an external clock EXT_CLK with a voltage level of VDD to generate the internal clock INT_CLK for the external clock EXT_CLK.

The conventional register controlled DLL of the SDRAM includes a clock divider 11, a phase comparator 12, a first delay line 13, a second delay line 14, a delay controller 15, a DLL driver 16, and a delay model circuit 17.

The internal clock TNT_CLK is then coupled to the first clock divider 11 and the first delay line 13. At the clock divider 11, the internal clock INT_CLK is divided by 1/n (where, n is a positive integer, and in this example, n=4) and a delay monitoring clock DVD4 and an inverted delay monitoring clock DVD4Z are generated. The delay monitoring clock DVD4 is coupled to the second delay line 14 and the inverted delay monitoring clock DVD4Z is provided to the phase comparator 12. The second delay line 14 receives the delay monitoring clock DVD4 to generate a delayed delay monitoring clock, which is then coupled to the delay model circuit 17. The delay model circuit 17 has a delay amount for modeling delay components of actual clock paths and data paths to thereby generate a delay model clock signal DVD4_DLY. The phase comparator 12 compares a phase of the delay model clock signal DVD4_DLY from the delay model circuit 17 with that of the inverted delay monitoring clock DVD4Z to generate a comparison signal.

The delay controller 15 controls delay amounts of the first and second delay lines 13 and 14 in response to the comparison signal. When the delay is locked, the DLL driver 16 drives an output from the first delay line 13 to thereby generate a DLL clock CLK_DLL. Here, the delay controller 15 includes a shift register and a shift controller for controlling a shift direction of the shift register. The delay controller 15 repeatedly controls the delay amount until the delay locking is achieved. Meanwhile, the delay model circuit 17 is a duplicate part of the actual clock path and data path, and determines a negative delay amount of the DLL.

FIG. 2 is a timing diagram of the conventional register controlled DLL shown in FIG. 1. Hereinafter, an operation of the conventional register controlled DLL will be described with reference to FIGS. 1 and 2.

First, the first clock divider 11 divides the internal clock INT_CLK by ¼ to generate the inverted delay monitoring clock DVD4Z. At this time, the inverted delay monitoring clock DVD4Z has an opposite phase to that of the delay monitoring clock DVD4.

At an initial operation, the delay monitoring clock DVD4 passes through only one of unit delay elements contained in the second delay line 14 and is coupled to the delay model circuit 17 which delays the delay monitoring clock DVD4 by a predetermined amount and outputs the delay model signal DVD4_DLY.

Meanwhile, the phase comparator 12 compares rising edges of the inverted delay monitoring clock DVD4Z with those of the delay model clock signal DVD4_DLY to generate the comparison signal CPR. The delay controller 15 determines the delay amounts of the first and second delay lines 13 and 14 in response to the comparison signal outputted from the phase comparator 12.

Then, the delay locking is achieved when the clock has a minimal jitter by repeatedly comparing the inverted delay monitoring clock DVD4Z with the delay model clock signal DVD4_DLY, and the DLL driver 16 is driven to generate the DLL clock CLK_DLL which synchronized with the external clock EXT_CLK.

As described above, the conventional register controlled DLL generates two divided clocks whose phases are opposite to each other. Among them, the delay monitoring clock DVD4 is delayed as much as D′ while passing through the second delay line 14 and as much as R while passing through the delay model circuit 17, so that the delay model clock signal DVD4_DLY outputted from the delay model circuit 17 is delayed as much as D′+R from the delay monitoring clock DVD4. The delay amount D′ of the second delay line 14 is repeatedly updated until the delay locking is achieved.

Here, in case where the phase is locked by adjusting D′ into D, the rising edge of the inverted delay monitoring clock DVD4Z is synchronized with that of the delay model clock signal DVD4_DLY, a following equation 1 is derived.

D+R=2T

or, D=2T−R Eq. 1

where T denotes a period of an external clock EXT_CLK.

Consequently, the DLL clock CLK_DLL is delayed as much as the delay amount D through the first delay line 13 and, therefore, the DLL clock CLK_DLL has the negative delay as much as the delay amount R of the delay model circuit 17 compared with the phase of the external clock EXT_CLK.

As described above, the conventional register controlled DLL includes the first delay line 13 for reflecting an adjusted delay time to the internal clock INT_CLK to generate the DLL clock CLK_DLL, and the second delay line 14 for adjusting an adjustable delay time for the delay locking by using the divided clock.

However, the conventional register controlled DLL requires two or more delay lines in order to finely adjust the delay time for the delay locking in a DDR SDRAM, while occupying large layout areas, so that a chip size of DDR SDRAM needs to be substantially increased. Additionally, there is a problem that as the number of delay lines is increased, a power consumption caused by the delay lines also increases.

### SUMMARY OF THE DISCLOSURE

Therefore, a register controlled delay locked loop (DLL) is disclosed, which is capable of decreasing the number of required delay lines in an effective manner.

A register controlled DLL for generating a delay locked clock synchronized with an external clock is disclosed, wherein the external clock is used in generating a internal clock, and wherein the register controlled DLL comprises: a first clock dividing circuit for dividing the internal clock by 1/N to generate a inverted and divided internal clock, N being a positive integer; a delay line for delaying the internal clock by a first delay amount wherein the first delay amount is updated by a control signal to generate a delayed internal clock; a second clock dividing circuit for dividing the delayed internal clock by 1/N to generate a divided and delayed internal clock; a delay model circuit for receiving and delaying the divided and delayed internal clock by a second delay amount to generating a delay model clock; a phase comparison circuit for comparing a phase of the delay model clock with that of the inverted and delayed internal clock to generate a comparison signal representing a difference therebetween; and a delay controlling circuit for generating the control signal in response to the comparison signal to thereby allowing the register controlled DLL to generate the delay locked clock.

Further, in an embodiment, a register controlled DLL for generating a delay locked clock synchronized with an external clock is disclosed, wherein the external clock is used in generating a internal clock, and wherein the registered controlled DLL comprises: a first clock dividing circuit for dividing the internal clock by 1/N to generate an inverted and divided internal clock, N being a positive integer; a delay line for delaying the internal clock by a first delay amount wherein the first delay amount is updated by a control signal to generate a delayed internal clock; a delay model circuit for receiving and delaying the delayed internal clock by a second delay amount to generating a delay model clock; a second clock dividing circuit for dividing the delay model clock by 1/N to generate a divided delay model clock; a phase comparison circuit for comparing a phase of the divided delay model clock with that of the inverted and delayed internal clock to generate a comparison signal representing a difference therebetween; and a delay controlling circuit for generating the control signal in response to the comparison signal to thereby allowing the register controlled DLL to generate the delay locked clock.

In a conventional register controlled DLL, a layout area occupied by the delay line is about ⅔ of a total layout area of the DLL. In contrast, the disclosed DLL can generate a delay locked DLL clock with only one delay line. For this, this invention is configured with an additional circuit structure, which can divide a delayed internal clock from the delay line and provide the divided and delayed internal clock to the delay model circuit. Accordingly, the layout area of the DLL is reduced and the current consumption is also reduced.

### BRIEF DESCRIPTION OF THE DRAWINGS

Other aspects of this disclosure will become apparent from the following description of the embodiments with reference to the accompanying drawings, wherein:

FIG. 1 is a block diagram showing a prior art register controlled DLL of an SDRAM;

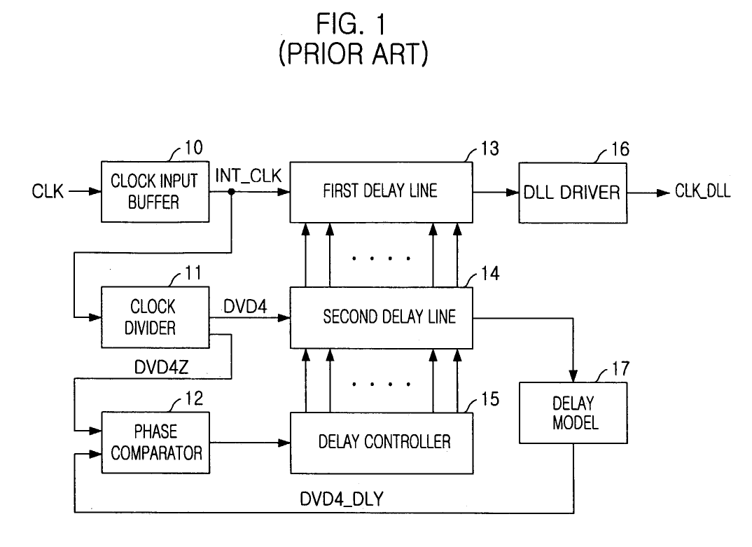

FIG. 2 is a timing diagram of the prior art register controlled DLL shown in FIG. 1;

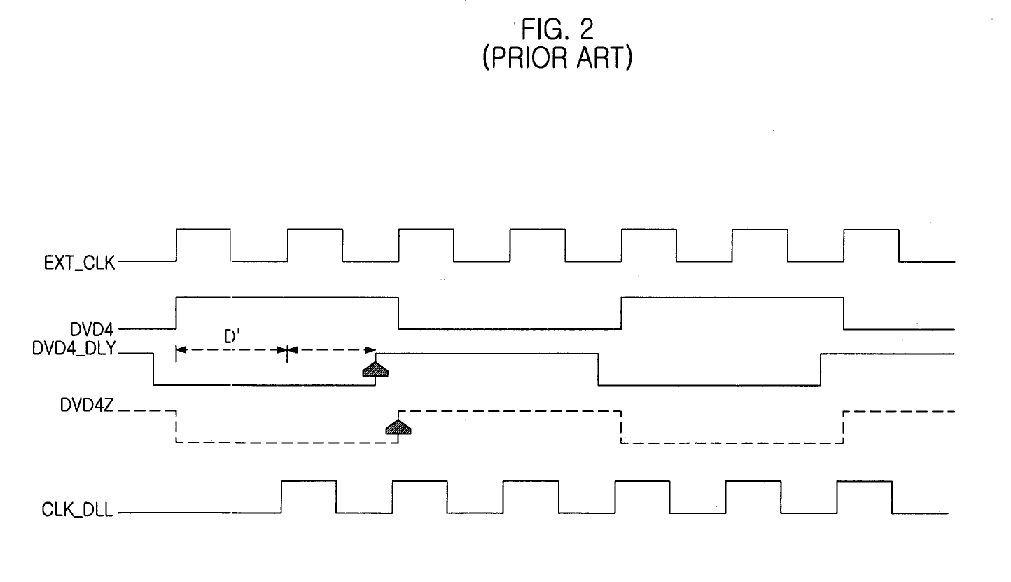

FIG. 3 is a block diagram illustrating a disclosed register controlled DLL of an SDRAM; and

FIG. 4 is a timing diagram of the register controlled DLL shown in FIG. 3.

### DETAILED DESCRIPTION OF THE PRESENTLY PREFERRED EMBODIMENTS

Hereinafter, a preferred embodiment will be descried in detail with reference to attached drawings.

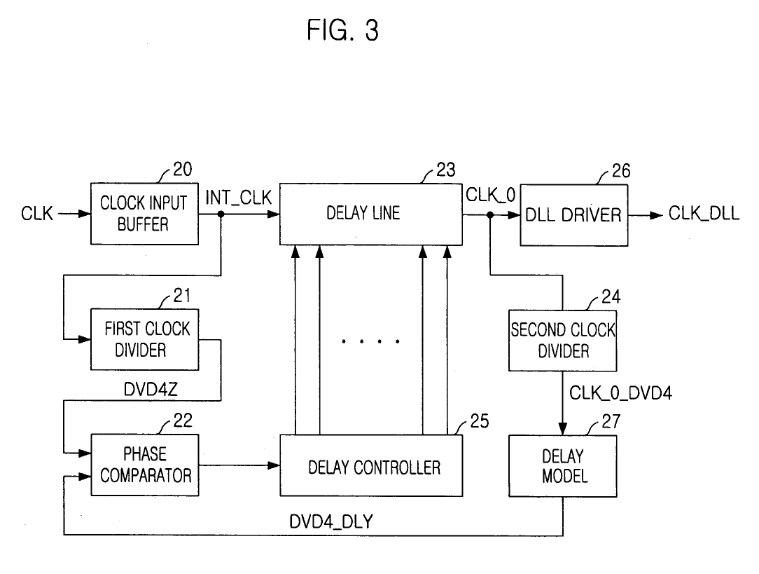

FIG. 3 is a block diagram illustrating a register controlled DLL of an SDRAM in accordance with a disclosed embodiment.

As shown, the register controlled DLL uses an internal clock INT_CLK outputted from a clock input buffer 20. The clock input buffer 20 temporarily stores an external clock EXT_CLK with a voltage level of VDD to generate the internal clock INT_CLK from the external clock EXT CLK.

The register controlled DLL of the SDRAM includes a first clock divider 21, a phase comparator 22, a delay line 23, a second clock divider 24, a delay controller 25, a DLL driver 26, and a delay model circuit 27.

The internal clock INT_CLK is then coupled to the first clock divider 21 and the delay line 23. At the first clock divider 21, the internal clock INT_CLK is divided and inverted by 1/n (where, n is a positive integer, and in this example, n=4) and an inverted delay monitoring clock DVD4Z is generated. The inverted delay monitoring clock DVD4Z is provided to the phase comparator 12.

On the other hand, the delay line 23 receives the internal clock INT_CLK for generating a delayed internal clock CLK_0, which is coupled to the second clock divider 24 and the DLL driver 26. At the second clock divider 24, the delayed internal clock CLK_0 is divided by 1/n (where, n is a positive integer, and in this example, n=4) to thereby generate a divided delayed internal clock CLK_0_DVD4, which is coupled to the delay model circuit 27. The delay model circuit 27 has a delay amount for modeling delay components of actual clock paths and data paths to thereby generate a delay model clock signal DVD4_DLY. The phase comparator 12 compares a phase of the delay model clock signal DVD4_DLY from the delay model circuit 17 with that of the inverted delay monitoring clock DVD4Z to generate a comparison signal. The delay controller 15 controls delay amounts of the delay lines 23 in response to the comparison signal.

When the delay is locked, the DLL driver 26 drives an output from the delay line 23 to thereby generate a DLL clock CLK_DLL. Here, the delay controller 25 includes a shift register and a shift controller for controlling a shift direction of the shift register. The delay controller 25 repeatedly controls the delay amount until the delay locking is achieved. Meanwhile, the delay model circuit 27 is a duplicate part of the actual clock path and data path, and determines a negative delay amount of the DLL.

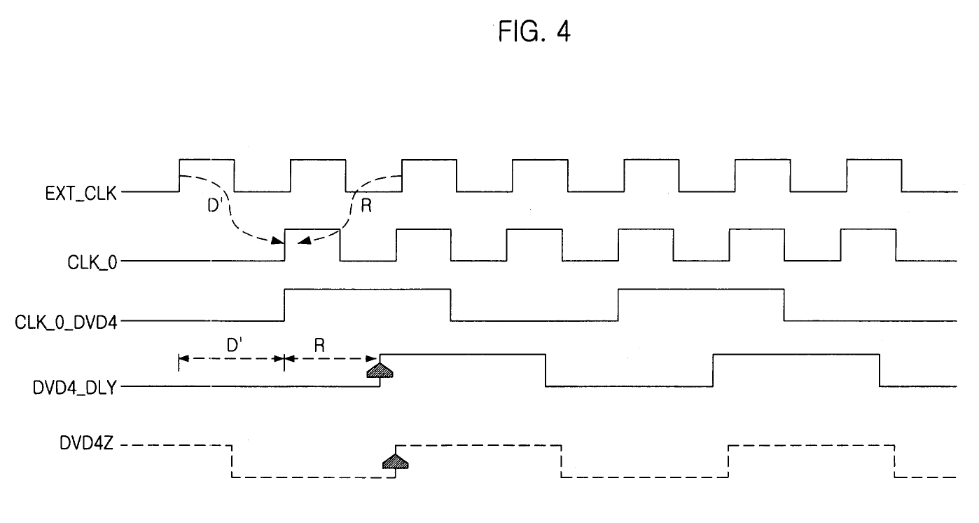

FIG. 4 is a timing diagram of the register controlled DLL shown in FIG. 3. Hereinafter, an operation of the register controlled DLL of the present invention will be described with reference to FIGS. 3 and 4.

Primarily, the internal clock INT_CLK outputted from the clock input buffer 20 is inputted to the first clock divider 21, and the first clock divider 21 divides the internal clock INT_CLK by four (4) to generate the inverted delay monitoring clock DVD4Z, which is synchronized one time for each fourth external clock EXT_CLK.

Additionally, the internal clock INT-CLK passes through only one of unit delay elements contained in the delay line 23 and is then outputted as a clock CLK_O. The second clock divider 24 divides the clock CLK_O into 1/n (where, n is a positive integer, and in this example, n=4), and an output CLK_O_DVD4 of the second clock divider 24 is delayed via the delay model circuit 27. If the delay in the delay line 23 is not considered, the output CLK-_O_DVD4 of the second clock divider 24 will have an opposite phase to the inverted delay monitoring clock DVD4Z outputted from the first clock divider 21.

Meanwhile, the phase comparator 22 compares rising edges of the inverted delay monitoring clock DVD4Z with those of the delay model clock signal DVD4_DLY to generate a comparison signal. The delay controller 25 determines the delay amounts of the delay line 23 in response to the comparison signal outputted from the phase comparator 22. The delay controller 25 includes a shift controller for generating a shift control signal used in controlling a shift direction in response to the comparison signal and a shift register for generating the control signal determining the delay amount of the delay line in response to the shift control signal.

Then, the delay locking is achieved when the clock has a minimal jitter by repeatedly comparing the inverted delay monitoring clock DVD4Z with the delay model clock signal DVD4_DLY whose delay amount is controlled, and the DLL driver 26 is driven to thereby generate the DLL clock CLK_DLL synchronized with the external clock EXT_CLK.

As described above, according to the disclosed register controlled DLL, the internal clock INT_CLK is delayed as much as “D” while passing through the delay line 23 and as much as “R” while passing through the delay model circuit 27, so that the internal clock INT_CLK is delayed as much as “D+R” in all. Even if the clock CLK_O outputted from the delay line 23 is divided via the second clock divider 24, it does not almost affect the delay.

Here, in case where the phase is locked, that is, the rising edge of the inverted delay monitoring clock DVD4Z is synchronized with that of the delay model clock signal DVD4_DLY, the above Eq. 1 is also applied.

Consequently, the DLL clock CLK_DLL is delayed as much as the delay amount D through the delay line 23 and, therefore, the DLL clock CLK_DLL has the negative delay as much as the delay amount R of the delay model circuit 27 compared with the phase of the external clock EXT_CLK.

As described above, the disclosed register controlled DLL of the SDRAM can generate the DLL clock with the negative delay using only one delay line. Therefore, a layout area of the DLL is remarkably reduced, resulting in a downscale of the semiconductor chip size. Further, decreasing the number of the delay lines can reduce current consumption. For example, according to a HSPICE simulation with respect to the disclosed DLL, in the case where the clock frequency is 133 MHz, the current consumption is reduced by much as 0.5 mA. It can be ascertained that the general characteristic of the DLL, e.g., a jitter, a delay locked time, etc., is similar to the prior art.

While the disclosed concepts have been described with respect to certain preferred embodiments only, other modifications and variation may be made without departing from the spirit and scope of this disclosure as set forth in the following claims.

For example, although the disclosed register controlled DLL of the SDRAM is described as an example, the disclosed register controlled DLL is applicable to other synchronous semiconductor memory devices, such as DDR SDRAM, or synchronous logics. If the disclosed DLL is applied to the DDR SDRAM, the required number of the delay lines can be reduced from three to two.

Further, although the case where the second clock divider is aligned between the delay line and the delay model circuit is disclosed, the principles of the disclosure are also applicable to the case where the second clock divider is aligned between the delay model circuit and the phase comparator so that the clock passing through the delay model circuit is divided and then compared in the phase comparator.

What is claimed is:

1. A register controlled DLL for generating a delay locked clock synchronized with an external clock, the external clock being used in generating an internal clock, the registered controlled DLL comprising:
a first clock dividing circuit for dividing the internal clock by 1/N to generate an inverted and divided internal clock, N being a positive integer;
a delay line for delaying the internal clock by a first delay amount wherein the first delay amount is updated by a control signal to generate a delayed internal clock;
a second clock dividing circuit for dividing the delayed internal clock by 1/N to generate a divided and delayed internal clock;
a delay model circuit for receiving and delaying the divided and delayed internal clock by a second delay amount to generating a delay model clock;
a phase comparison circuit for comparing a phase of the delay model clock with that of the inverted and delayed internal clock to generate a comparison signal representing a difference therebetween; and
a delay controlling circuit for generating the control signal in response to the comparison signal to thereby allowing the register controlled DLL to generate the delay locked clock.

2. The register controlled DLL as recited in claim 1, further comprising a DLL clock drive circuit for driving the delay locked clock when a delay locking is achieved.

3. The register controlled DLL as recited in claim 2, wherein the delay controlling circuit includes:
a shift controller for generating a shift control signal used in controlling a shift direction in response to the comparison signal; and
a shift register for generating the control signal used in determining the delay amount of the delay line in response to the shift control signal.

4. The register controlled DLL as recited in claim 2, further comprising a clock buffer for generating the input clock in response to the external clock.

5. The register controlled DLL as recited in claim 2, wherein N is 4.

6. A register controlled DLL for generating a delay locked clock synchronized with an external clock, the external clock being used in generating a internal clock, registered controlled DLL comprising:
a first clock dividing circuit for dividing the internal clock by 1/N to generate an inverted and divided internal clock, N being a positive integer;
a delay line for delaying the internal clock by a first delay amount wherein the first delay amount is updated by a control signal to generate a delayed internal clock;
a delay model circuit for receiving and delaying the delayed internal clock by a second delay amount to generate a delay model clock;
a second clock dividing circuit for dividing the delay model clock by 1/N to generate a divided delay model clock;
a phase comparison circuit for comparing a phase of the divided delay model clock with that of the inverted and delayed internal clock to generate a comparison signal representing a difference therebetween; and
a delay controlling circuit for generating the control signal in response to the comparison signal to thereby allowing the register controlled DLL to generate the delay locked clock.

7. The register controlled DLL as recited in claim 6, further comprising a DLL clock drive circuit for driving the delay locked clock when a delay locking is achieved.

8. The register controlled DLL as recited in claim 7, wherein the delay controlling circuit includes:
a shift controller for generating a shift control signal used in controlling a shift direction in response to the comparison signal; and
a shift register for generating the control signal used in determining the delay amount of the delay line in response to the shift control signal.

9. The register controlled DLL as recited in claim 7, further comprising a clock buffer for generating the input clock in response to the external clock.

10. The register controlled DLL as recited in claim 7, wherein N is 4.
